(19) United States
(12) Patent Application Publication
(10) Pub. No.: US 2014/0003167 A1
(43) Pub. Date: Jan. 2, 2014

(54) NONVOLATILE MEMORY DEVICE, OPERATING METHOD THEREOF, AND DATA STORAGE DEVICE HAVING THE SAME

(71) Applicant: SK HYNIX INC., Icheon-si (KR)

(72) Inventor: Sung Hyun JUNG, Icheon-si (KR)

(73) Assignee: SK HYNIX INC., Icheon-si (KR)

(21) Appl. No.: 13/710,895

(22) Filed: Dec. 11, 2012

(30) Foreign Application Priority Data
Jun. 27, 2012 (KR) 10-2012-0069134

(51) Int. Cl. G11C 7/00

(52) U.S. Cl. CPC G11C 7/00
USPC 365/189.14

(57) ABSTRACT

A nonvolatile memory device including a plurality of memory cells arranged at a region where word lines and bit lines cross each other; a plurality of data read/write circuits divided into a plurality of groups, and configured to store data in the memory cells or read data stored in the memory cells, according to an operation mode; a pass/fail check unit configured to determine a pass/fail of an operation for each of the data read/write circuit groups; and a current sensing check unit configured to selectively perform a fail bit count operation on the data read/write circuit groups, according to a determination result of the pass/fail check unit.

### CROSS-REFERENCES TO RELATED APPLICATION

The present application claims priority under 35 U.S.C. §119(a) to Korean application number 10-2012-0069134, filed on Jun. 27, 2012, in the Korean Intellectual Property Office, which is incorporated herein by reference in its entirety.

### BACKGROUND

1. Technical Field

The present invention generally relates to a semiconductor memory device, and more particularly, to a nonvolatile memory device, an operating method thereof, and a data storage device is having the same.

2. Related Art

In general, a semiconductor memory device is classified into a volatile memory device and a nonvolatile memory device. The volatile memory device loses data stored therein when power supply is cut off, but the nonvolatile memory device maintains data stored therein even though power supply is cut off. The nonvolatile memory device may include various types of memory cells.

The nonvolatile memory device may be divided into a flash memory device, a ferroelectric RAM (FRAM) using a ferroelectric capacitor, a magnetic RAM (MRAM) using a tunneling magneto-resistive (TMR) layer, a phase change memory device using chalcogenide alloys and the like, depending on the structure of memory cells.

Among the nonvolatile memory devices, the flash memory device is roughly divided into a NOR flash memory device and a NAND flash memory device, depending on the connection state between memory cells and a bit line. The NOR flash memory device has a structure in which two or more memory cell transistors are connected in parallel to one bit line. Therefore, the NOR flash memory device has an excellent random access time characteristic. On the other hand, the NAND flash memory device has a structure in which two or more memory cell transistors are connected in series to one bit line. Such a structure is referred to as a cell string, and one bit line contact is required per one cell string. Therefore, the NAND is flash memory device has an excellent characteristic in terms of integration degree.

The nonvolatile memory device may perform a program or erase operation through a plurality of operation loops. Depending on whether the program or erase operation was passed or failed, it is possible to decide whether or not to repeat the operation loop. Alternatively, depending on whether the program or erase operation was passed or failed, it is possible to complete or abnormally end the corresponding operation. Therefore, the nonvolatile memory device requires a pass/fail check operation to check whether a program or erase operation was passed or failed, during the corresponding operation. When the pass/fail check operation time is reduced, the operating speed of the nonvolatile memory device may be improved.

### SUMMARY

A nonvolatile memory device capable of reducing a pass/fail check time of an operation, an operating method thereof, and a data storage device having the same are described herein.

In an embodiment, a nonvolatile memory device includes: a plurality of memory cells arranged at a region where word lines and bit lines cross each other; a plurality of data read/write circuits divided into a plurality of groups, and configured to store data in the memory cells or read data stored in the memory cells, according to an operation mode; a pass/fail check unit configured to determine a pass/fail of an operation for each of the data read/write circuit groups; and a current sensing check unit configured to selectively perform a fail bit count operation on the data read/write circuit groups, according to a determination result of the pass/fail check unit.

In an embodiment, an operating method of a nonvolatile memory device includes the steps of: determining whether an operation of a data read/write circuit group including a plurality of data read/write circuits is passed or failed; and when the operation of the data read/write circuit group is failed, counting a fail bit number of the data read/write circuit group.

In an embodiment, a data storage device includes: a nonvolatile memory device; and a controller configured to control the nonvolatile memory device, wherein the nonvolatile memory device includes: a plurality of memory cells arranged at a region where word lines and bit lines cross each other; a plurality of data read/write circuits divided into a plurality of groups, and configured to store data in the memory cells or read data stored in the memory cells, according to an operation mode; a pass/fail check unit configured to determine a pass/fail of an operation for each of the data read/write circuit groups; and a current sensing check unit configured to selectively perform a fail bit count operation on the data read/write circuit groups, according to a determination result of the pass/fail check unit.

### BRIEF DESCRIPTION OF THE DRAWINGS

Features, aspects, and embodiments are described in conjunction with the attached drawings, in which:

FIG. 1 is a block diagram illustrating a nonvolatile memory device according to an embodiment;

FIG. 2 is a block diagram illustrating a pass/fail check circuit and a current sensing check circuit according to an embodiment;

FIG. 3 is a circuit diagram of the pass/fail check circuit according to an embodiment;

FIG. 4 is a block diagram of the current sensing check circuit according to an embodiment;

FIG. 5 is a flow chart showing an operating method of the nonvolatile memory device according to an embodiment;

FIG. 6 is a block diagram illustrating a data processing system including the nonvolatile memory device according to an embodiment;

FIG. 7 illustrates a memory card including a nonvolatile memory device according to an embodiment;

FIG. 8 is a block diagram illustrating the internal configuration of the memory card illustrated in FIG. 7 and the connection relation between the memory card and a host;

FIG. 9 is a block diagram illustrating an SSD including the nonvolatile memory device according to an embodiment;

FIG. 10 is a block diagram illustrating an SSD controller illustrated in FIG. 9; and

FIG. 11 is a block diagram illustrating a computer system in which a data storage device having the nonvolatile memory device according to an embodiment is mounted.

### DETAILED DESCRIPTION

Hereinafter, a nonvolatile memory device, an operating method thereof, and a data storage device having the same according to various embodiments will be described below with reference to the accompanying drawings through the various embodiments.

Various embodiments will be described below in detail with reference to the accompanying drawings. The various embodiments may, however, be embodied in different forms and should not be construed as limited to the embodiments set forth herein. Rather, these embodiments are provided so that this disclosure will be thorough and complete, and will fully convey the scope of the present invention to those skilled in the art.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention. Additionally, the same reference numerals or the same reference designators may denote the same elements throughout the specification.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

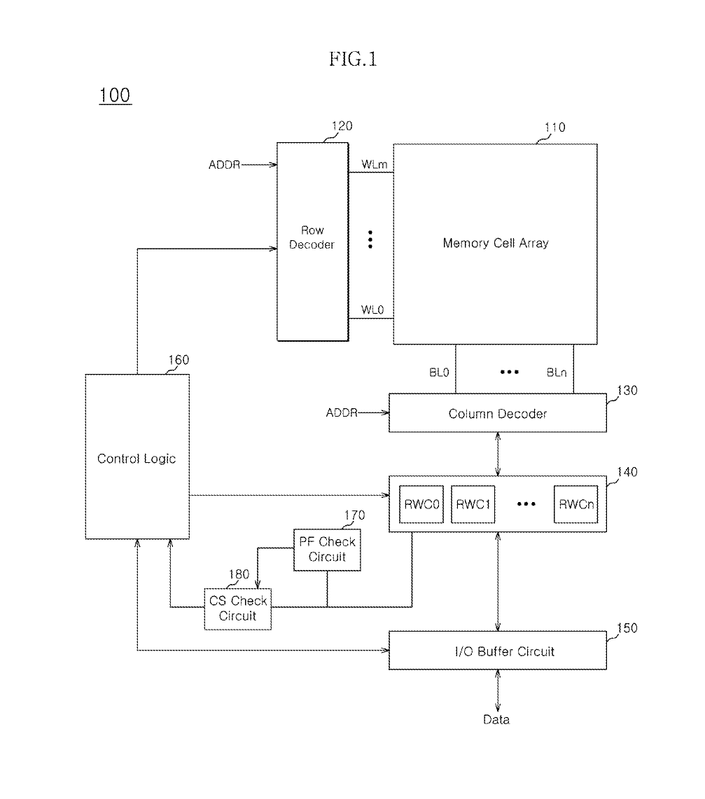

FIG. 1 is a block diagram illustrating a nonvolatile memory device according to an embodiment. Referring to FIG. 1, the nonvolatile memory device 100 may include a memory cell array 110, a row decoder 120, a column decoder 130, a data read/write circuit 140, an input/output (I/O) buffer circuit 150, a control logic 160, a pass/fail check circuit 170 (i.e., pass/fail check unit), and a current sensing check circuit 180.

The memory cell array 110 may include a plurality of memory cells arranged at the respective intersections between bit lines BL0 to BLn and word lines WL0 to WLm. Each of the memory cells may store one-bit data. Such a memory cell is referred to as a single level cell (SLC). The SLC may be programmed in such a manner as to have a threshold voltage corresponding to an erase state and one program state. As another example, each of the memory cells may store two or more-bit data. Such a memory cell is referred to as a multi-level cell (MLC). The MLC may be programmed in such a manner as to have a threshold voltage corresponding to an erase state and any one of a plurality of program states. The memory cell array 110 may be implemented to have a single-layer array structure or multi-layer array structure. The single-layer array structure is referred to as a 2D array structure, and the multi-layer array structure is referred to as a 3D array structure.

The row decoder 120 may operate according to the control of the control logic 160. The row decoder 120 may be connected to the memory cell array 110 through the plurality of word lines WL0 to WLm. The row decoder 120 may be configured to decode an address ADDR inputted from outside. The row decoder 120 may be configured to selectively drive the word lines WL0 to WLm according to the decoding result. For example, the row decoder 120 may provide a select voltage to a selected word line, and provide an unselect voltage to an unselected word line.

The column decoder 130 may operate according to the control of the control logic 160. The column decoder 130 may be connected to the memory cell array 110 through the bit lines BL0 to BLn. The column decoder 130 may be configured to decode the address ADDR. The column decoder 130 may be configured to sequentially connect the bit lines BL0 to BLn to the data read/write circuit 140 in a predetermined unit according to the decoding result.

The data read/write circuit 140 may operate according to the control of the control logic 160. The data read/write circuit 140 may be configured to operate as a write driver or sense amplifier depending on an operation mode. For example, the data read/write circuit 140 may be configured to store data inputted through the I/O buffer circuit 150 in a memory cell of the memory cell array 110 during a program operation. For another example, the data read/write circuit 140 may be configured to output data read from a memory cell of the memory cell array 110 to the I/O buffer circuit 150 during a read operation.

The data read/write circuit 140 may include a plurality of data read/write circuits RWC0 to RWCn corresponding to the respective bit lines BL0 to BLn (or bit line pairs). For this reason, the bit lines BL0 to BLn (or bit line pairs) may be selected or controlled by the corresponding data read/write circuits RWC0 to RWCn, respectively.

The I/O buffer circuit 150 may be configured to receive data from an external device (for example, a memory controller, a memory interface, a host device or the like) or output data to the external device. For this operation, the I/O output buffer circuit 150 may include a data latch circuit (not illustrated) and an output driving circuit (not illustrated).

The control logic 160 may be configured to control overall operations of the nonvolatile memory device 100 in response to a control signal provided from the external device. For example, the control logic 160 may control read, program (or write), and erase operations of the nonvolatile memory device 100.

The control logic 160 may be configured to control a read, program, or erase operation according to a check result provided from the current sensing check circuit 180. For example, the control logic 160 may repeat an operation, which is performed through a plurality of operation loops, up to a maximum loop number depending on the check result provided from the current sensing check circuit 180. For another example, the control logic 160 may abnormally end the operation according to the check result provided from the current sensing check circuit 180.

For this operation, the pass/fail check circuit 170 may be configured to determine a pass/fail signal provided from the data read/write circuit 140. That is, the pass/fail check circuit 170 may be configured to determine whether the pass/fail signal provided from the data read/write circuit 140 indicates a pass or fail of an operation. Hereafter, the operation of the pass/fail check circuit 170 will be referred to as a pass/fail determination operation. The determination result of the pass/fail check circuit 170 may be provided to the current sensing check circuit 180.

The current sensing check circuit 180 may be configured to sense the magnitude of the pass/fail signal provided from the data read/write circuit 140. That is, the current sensing check circuit 180 may be configured to compare a reference voltage to the magnitude of the pass/fail signal, and determine how many data read/write circuits were failed among the data read/write circuits RWC0 to RWCn, according to the comparison result. For example, the current sensing check circuit 180 may be configured to provide information on whether the number of failed data read/write circuits is greater or less than a threshold value, to the control logic 160. Hereafter, the operation of the current sensing check circuit 180 will be referred to as a fail bit count operation.

According to an embodiment, the data read/write circuit 140 may be divided into a plurality of operating groups. The pass/fail check circuit 170 may perform a pass/fail determination operation on each of the operating groups, and may provide the determination result to the current sensing check circuit 180. Furthermore, the current sensing check circuit 180 selectively may perform the fail bit count operation on the operating groups of the data read/write circuit 140 according to the determination result provided from the pass/fail check circuit 170. For example, the current sensing check circuit 180 may perform the fail bit count operation only on data read/write circuits RWC0 to RCWk which are determined to be a fail by the pass/fail determination operation. This means that the number of fail bit count operations to be performed is reduced, that is, the operating speed of the nonvolatile memory device is improved.

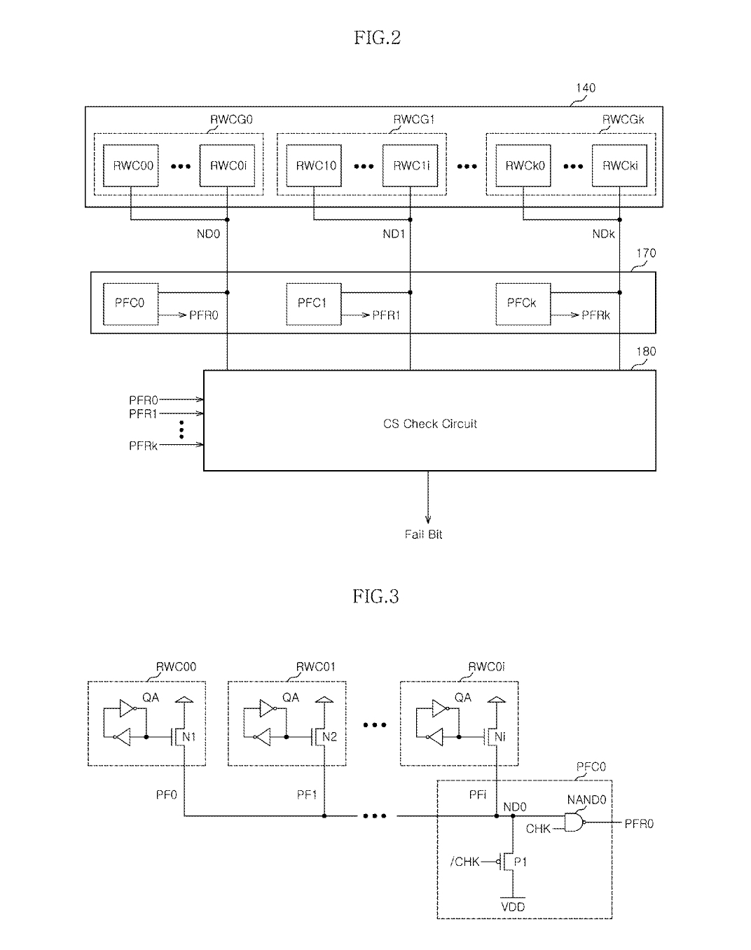

FIG. 2 is a block diagram illustrating the pass/fail check circuit and the current sensing check circuit according to an embodiment.

The data read/write circuit 140 may include a plurality of data read/write circuits RWC00 to RCWki. The data read/write circuits RWC00 to RCWki are divided into a plurality of operating groups, that is, a plurality of data/write circuit groups RWCG0 to RWCGk.

The pass/fail check circuit 170 may include a plurality of pass/fail check circuits PFC0 to PFCk. The respective pass/fail check circuits PFC0 to PFCk perform a pass/fail determination operation on the corresponding data read/write circuit groups RWCG0 to RWCGk.

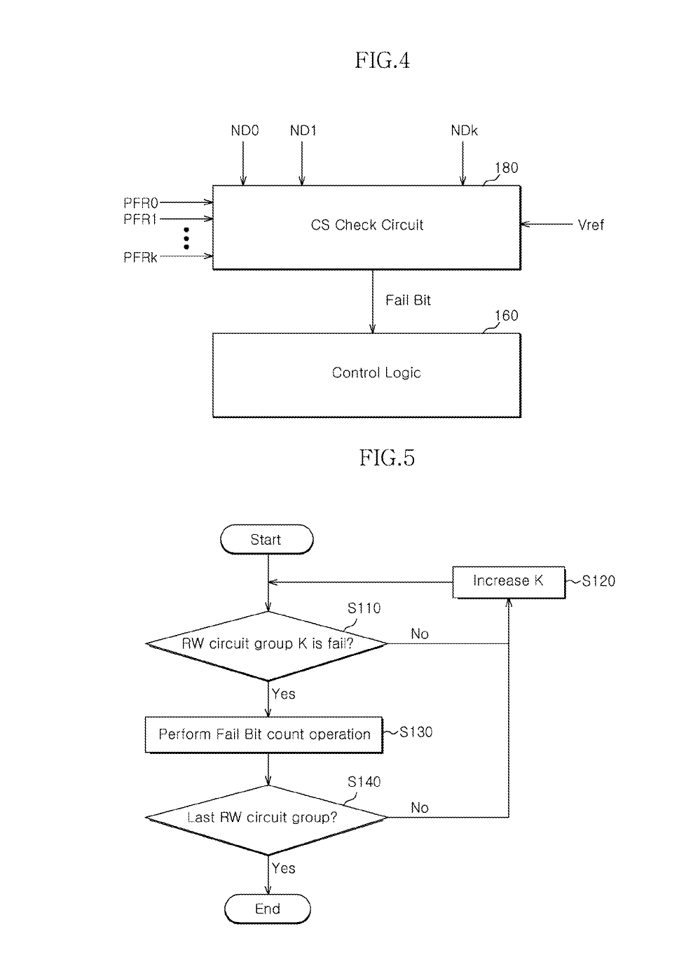

Referring to FIG. 3, the pass/fail check circuit 170 will be described. FIG. 3 is a circuit diagram illustrating the pass/fail check circuit according to an embodiment. For convenience of description, FIG. 3 illustrates the pass/fail check circuit PFC0 to perform a pass/fail determination operation on data read/write circuits RWC00 to RWC0i included in the data read/write circuit group RWCG0 (see FIG. 2). For convenience of description, the data read/write circuits RWC00 to RWC0i are illustrated in a latch type.

The pass/fail check circuit PFC0 may include a pull-up element P1 and a NAND gate NAND0. The pull-up element P1 may be configured to provide a power supply voltage VDD to a pass/fail sensing node ND0 according to a pass/fail check bar signal /CHK. The NAND gate NAND0 may be configured to perform an NAND operation on the state of the pass/fail sensing node ND0 and a pass/fail check signal CHK, and output a determination result PFR0. The pass/fail sensing node ND0 may be connected to pull-down elements N1 to Ni configured to provide a ground voltage according to the states of specific nodes QA of the respective data read/write circuits RWC00 to RWC0i. That is, the pass/fail check circuit PFC0 may be configured to determine whether pass/fail signals PF0 to PFi generated according to the states of the specific nodes QA of the respective data read/write circuits RWC00 to RWC0i indicate a pass or fail of operation.

For example, when data “1” is stored in one or more specific nodes QA among the data read/write circuits RWC00 to RWC0i, the pull-down elements N1 to Ni are turned on because the pull-down elements N1 to Ni are connected in parallel, and a ground voltage indicating a fail of operation is applied to the pass/fail sensing node ND0. As the pass/fail check signal CHK is activated, the NAND gate NAND0 outputs a determination result PFR0 indicating a fail of operation, even though the high-level pass/fail check signal CHK is provided to the NAND gate NAND0. On the other hand, when data “0” is stored in the specific nodes QA of all the data read/write circuits RWC00 to RWC0i, the pull-down elements N1 to Ni are turned off, and the pass/fail sensing node ND0 is floated. When the low-level pass/fail check bar signal /CHK is provided to the pull-up element P1 by the activation of the pass/fail check signal CHK, the power supply voltage VDD is applied to the pass/fail sensing node ND0. Therefore, the NAND gate NAND0 outputs a determination result PFR0 indicating a pass of operation.

Referring to FIG. 2, the pass/fail check circuits PFC0 to PFCk provide determination results PFR0 to PFRk of the pass/fail determination operation to the current sensing check circuit 180. The current sensing check 180 selectively may perform a fail bit count operation on the data read/write circuit groups RWCG0 to RWCGk, based on the determination results PFR0 to PFRk of the pass/fail determination operation, respectively. That is, the current sensing check circuit 180 may perform the fail bit count operation only on data read/write circuit groups which are determined to be a fail through the pass/fail determination operation.

Referring to FIG. 4, the current sensing check circuit 180 will be described. FIG. 4 is a block diagram for explaining the current sensing check circuit according to an embodiment. The current sensing check circuit 180 discriminates data read/write circuit groups where the pass/fail determination operation is a fail, based on the determination results PFR0 to PFRk of the pass/fail determination operation. The current sensing check circuit 180 may be configured to sense the magnitude of a pass/fail signal provided from a data read/write circuit group where the pass/fail determination operation is determined to be a fail.

As described above with reference to FIG. 3, the magnitude of a voltage (or current) applied to the pass/fail sensing node ND0 is set according to pass/fail signals of the data read/write circuits RWC00 to RWC0i included in the data read/write circuit group RWCG0 (see FIG. 2). The current sensing check circuit 180 compares a reference voltage Vref (or reference current) to a voltage (or current) applied to a pass/fail sensing node (for example, any one of the pass/fail sensing nodes ND0 to NDk) of a data read/write circuit group where the pass/fail determination operation was determined to be a fail. That is, the current sensing check circuit 180 may perform a fail bit count operation on the data read/write circuit group where the pass/fail determination operation was determined to be a fail. As a result, the current sensing check circuit 180 may provide information on whether the number of fails occurring in the corresponding data read/write circuit group is greater or less than a threshold value, to the control logic 160. Additionally, the reference voltage Vref may be set according to the fail bit threshold value.

According to an embodiment, the fail bit count operation of the current sensing check circuit 180 may be selectively performed according to the result of the pass/fail determination operation which is performed on each of the data read/write circuit groups RWCG0 to RWCGk by the pass/fail check circuit 170. Therefore, the number of fail bit count operations to be performed may be reduced.

FIG. 5 is a flow chart showing an operating method of the nonvolatile memory device according to an embodiment. The nonvolatile memory device requires a pass/fail check operation for checking whether an operation (for example, a program or erase operation) was passed or failed and a fail bit count operation for checking whether the number of fail bits falls within an effective range, when the operation was failed. According to the check result, a plurality of operation loops may be repeated, or the operation may be abnormally ended. The pass/fail check operation and the fail bit count operation may be sequentially performed on the data read/write circuit groups RWCG0 to RWCGk of FIG. 2.

At step S110 (i.e., RW circuit group K is fail?), a pass/fail check operation is performed on a selected data read/write circuit group K, and whether the pass/fail check operation is a pass or fail is determined. When the pass/fail check result for the selected data read/write circuit group K is a pass (i.e., No), the procedure proceeds to step S120. On the other hand, when the pass/fail check result for the selected data read/write circuit group K is a fail (i.e., Yes), the procedure proceeds to step S130.

At step S120 (i.e., increase K), another data read/write circuit group is selected. For example, a data read/write circuit group K+1 where a pass/fail check operation is to be performed after the current data read/write circuit group K is selected. Then, the procedure proceeds to step S110.

At step S130 (i.e., Perform Fail Bit count operation), a fail bit count operation is performed on the data read/write circuit group K where the pass/fail check operation is failed. According to the result of the fail bit count operation, a main operation (for example, a program or erase operation) may be normally completed or abnormally ended.

At step S140 (i.e., Last RW circuit group), whether a pass/fail check operation for the last data read/write circuit group was performed or not is determined. When the pass/fail check operation for the last data read/write circuit group is not performed (i.e., No), the procedure proceeds to step S120. Then, the pass/fail check operation is repetitively performed until the pass/fail check operation for the last data read/write circuit group is performed (i.e., Yes).

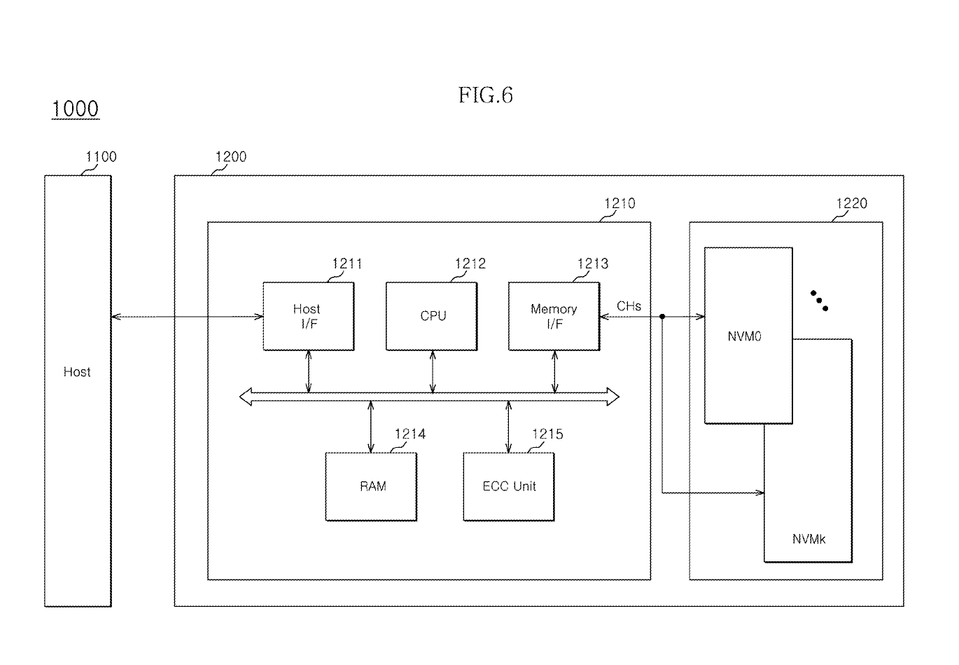

FIG. 6 is a block diagram illustrating a data processing system including the nonvolatile memory device according to an embodiment. Referring to FIG. 6, the data processing system 1000 may include a host 1100 and a data storage device 1200. The data storage device 1200 may include a controller 1210 and a data storage medium 1220. The data storage device 1200 may be connected to the host 1100 such as a desktop computer, a notebook computer, a digital camera, a mobile phone, an MP3 player, a game machine or the like. The data storage device 1200 is also referred to as a memory system.

The controller 1210 is coupled to the host 1100 and the data storage medium 1220. The controller 1210 may be configured to access the data storage medium 1220 in response to a request from the host 1100. For example, the controller 1210 may be configured to control a read, program, or erase operation of the data storage medium 1220. The controller 1210 may be configured to drive firmware for controlling the data storage medium 1220.

The controller 1210 may include well-known components such as a host interface 1211, a central processing unit (CPU) 1212, a memory interface 1213, a RAM 1214, and an error correction code (ECC) unit 1215.

The CPU 1212 may be configured to control overall operations of the controller 1210 in response to a request of the host. The RAM 1214 may be used as a working memory of the CPU 1212. The RAM 1214 may temporarily store data read from the data storage medium 1220 or data provided from the host 1100.

The host interface 1211 may be configured to interface the host 1100 and the controller 1210. For example, the host interface 1211 may be configured to communicate with the host 1100 through one of a USB (Universal Serial Bus) protocol, a MMC (Multimedia Card) protocol, a PCI (Peripheral Component Interconnection) protocol, a PCI-E (PCI-Express) protocol, a PATA (Parallel Advanced Technology Attachment) protocol, a SATA (Serial ATA) protocol, an SCSI (Small Computer System Interface) protocol, SAS(Serial SCSI) protocol, and an IDE (Integrated Drive Electronics) protocol.

The memory interface 1213 may be configured to interface the controller 1210 and the data storage medium 1220 though channels CHs. The memory interface 1213 may be configured to provide a command and an address to the data storage medium 1220. Furthermore, the memory interface 1213 may be configured to exchange data with the data storage medium 1220.

The data storage medium 1220 may be configured with the nonvolatile memory device 100 of FIG. 1 according to an embodiment. The data storage medium 1220 may include a plurality of nonvolatile memory devices NVM0 to NVMk. As the data storage medium 1220 may be configured with the nonvolatile memory device 100 according to an embodiment, the operating speed of the data storage device 1200 may be increased, and the power consumption may be reduced.

The ECC unit 1215 may be configured to detect an error of the data read from the data storage medium 1220. Furthermore, the ECC unit 1215 may be configured to correct the detected error, when the detected error falls within a correction range. Additionally, the ECC unit 1215 may be provided inside or outside the controller 1210 depending on the memory system 1000.

The controller 1210 and the data storage medium 1220 may be integrated to form a solid state drive (SSD).

As another example, the controller 1210 and the data storage medium 1220 may be integrated into one semiconductor device to form a memory card. For example, the controller 1210 and the data storage medium 1220 may be integrated into one semiconductor device to form a PCMCIA (personal computer memory card international association) card, a CF (compact flash) card, a smart media card, a memory stick, a multi-media card (MMC, RS-MMC, or MMC-micro), an SD (secure digital) card (SD, Mini-SD, or Micro-SD), or a UFS (universal flash storage) card.

As another example, the controller 1210 or the data storage medium 1220 may be mounted in various types of packages. For example, the controller 1210 or the data storage medium 1220 may be packaged and mounted according to various methods such as POP (package on package), ball grid arrays (BGAs), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat package (MQFP), thin quad flat package (TQFP), small outline IC (SOIC), shrink small outline package (SSOP), thin small outline package (TSOP), thin quad flat package (TQFP), system in package (SIP), multi chip package (MCP), wafer-level fabricated package (WFP), and wafer-level processed stack package (WSP).

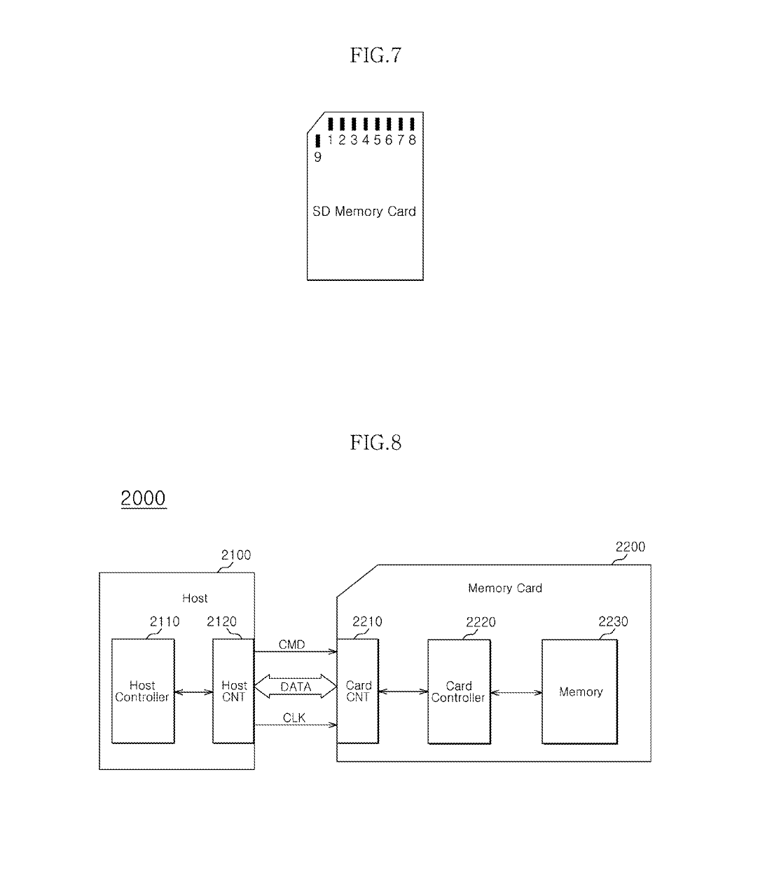

FIG. 7 illustrates a memory card including the nonvolatile memory device according to an embodiment. FIG. 7 illustrates the exterior of an SD (secure digital) card among memory cards.

Referring to FIG. 7, the SD card may include one command pin (for example, second pin), one clock pin (for example, fifth pin), four data pins (for example, first, seventh, eighth, and ninth pins), and three power supply pins (for example, third, fourth, and sixth pins).

Through the command pin (second pin), a command and a response signal are transferred. In general, the command is transmitted to the SD card from a host, and the response signal is transmitted to the host from the SD card.

The data pins (first, seventh, eighth, and ninth pins) are divided into receive (Rx) pins for receiving data transmitted from the host and transmit (Tx) pins for transmitting data to the host. The Rx pins and the Tx pins, respectively, form a pair to transmit differential signals.

The SD card may include the nonvolatile memory device 100 of FIG. 1 according to an embodiment and a controller for controlling the nonvolatile memory device. The controller included in the SD card may have the same configuration and function as the controller 1210 described with reference to FIG. 6.

FIG. 8 is a block diagram illustrating the internal configuration of the memory card illustrated in FIG. 7 and the connection relation between the memory card and a host. Referring to FIG. 8, the data processing system 2000 may include a host 2100 and a memory card 2200. The host 2100 may include a host controller 2110 and a host connection unit 2120. The memory card 2200 may include a card connection unit 2210, a card controller 2220, and a memory device 2230.

The host connection unit 2120 and the card connection unit 2210 include a plurality of pins. The pins may include a command pin, a clock pin, a data pin, and a power supply pin. The number of pins may differ depending on the type of the memory card 2200.

The host 2100 stores data in the memory card 2200 or reads data stored in the memory card 2200.

The host controller 2110 transmits a write command CMD, a clock signal CLK generated from a clock generator (not illustrated) inside the host 2100, and data DATA to the memory card 2200 through the host connection unit 2120. The card controller 2220 may operate in response to the write command received through the card connection unit 2210. The card controller 2220 stores the received data DATA in the memory device 2230, using a clock signal generated from a clock generator (not illustrated) inside the card controller 2220, according to the received clock signal CLK.

The host controller 2110 transmits a read command CMD and the clock signal CLK generated from the clock generator inside the host device 2100 to the memory card 2200 through the host connection unit 2120. The card controller 2220 may operate in response to the read command received through the card connection unit 2210. The card controller 2220 reads data from the memory device 2230 using the clock signal generated from the clock generator inside the card controller 2220, according to the received clock signal CLK, and transmits the read data to the host controller 2110.

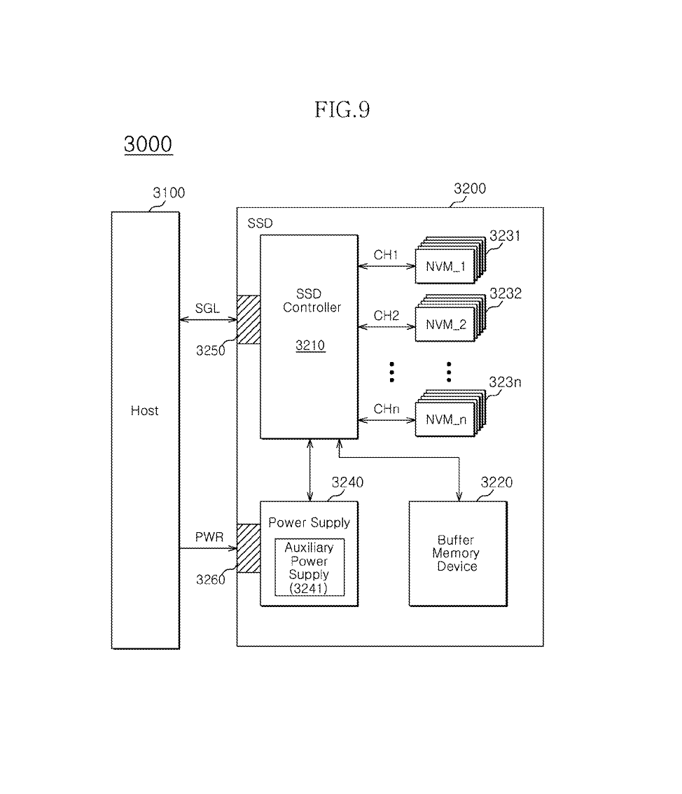

FIG. 9 is a block diagram illustrating an SSD including the nonvolatile memory device according to an embodiment. Referring to FIG. 9, a data processing system 3000 may include a host 3100 and an SSD 3200.

The SSD 3200 may include an SSD controller 3210, a buffer memory device 3220, a plurality of nonvolatile memory devices 3231 to 323n, a power supply 3240, a signal connector 3250, and a power connector 3260.

The SSD 3200 may operate in response to a request of the host device 3100. That is, the SSD controller 3210 may be configured to access the nonvolatile memory devices 3231 to 323n in response to a request from the host 3100. For example, the SSD controller 3210 may be configured to control read, program, and erase operations of the nonvolatile memory devices 3231 to 323n.

The buffer memory device 3220 may be configured to temporarily store data which are to be stored in the nonvolatile memory devices 3231 to 323n. Furthermore, the buffer memory device 3220 may be configured to temporarily store data read from the nonvolatile memory devices 3231 to 323n. The data temporarily stored in the buffer memory device 3220 are transmitted to the host 3100 or the nonvolatile memory devices 3231 to 323n, according to the control of the SSD controller 3210.

The nonvolatile memory devices 3231 to 323n are used as storage media of the SSD 3200. Each of the nonvolatile memory devices 3231 to 323n may include the nonvolatile memory device 100 of FIG. 1 according to an embodiment. Therefore, the operating speed of the SSD 3200 may be increased.

The respective nonvolatile memory devices 3231 to 323n are connected to the SSD controller 3210 through a plurality of channels CH1 to CHn. One channel may be connected to one or more nonvolatile memory devices. The nonvolatile memory devices connected to one channel may be connected to the same signal bus and data bus.

The power supply 3240 may be configured to provide power PWR inputted through the power connector 3260 into the SSD 3200. The power supply 3240 may include an auxiliary power supply 3241. The auxiliary power supply 3241 may be configured to supply power to normally terminate the SSD 3200, when sudden power off occurs. The auxiliary power supply 3241 may include super capacitors capable of storing the power PWR.

The SSD controller 3210 may be configured to exchange signals SGL with the host 3100 through the signal connector 3250. Here, the signals SGL may include commands, addresses, data and the like. The signal connector 3250 may include a connector such as PATA (Parallel Advanced Technology Attachment), SATA (Serial Advanced Technology Attachment), SCSI (Small Computer System Interface), or SAS (Serial SCSI), according to the interface method between the host 3100 and the SSD 3200.

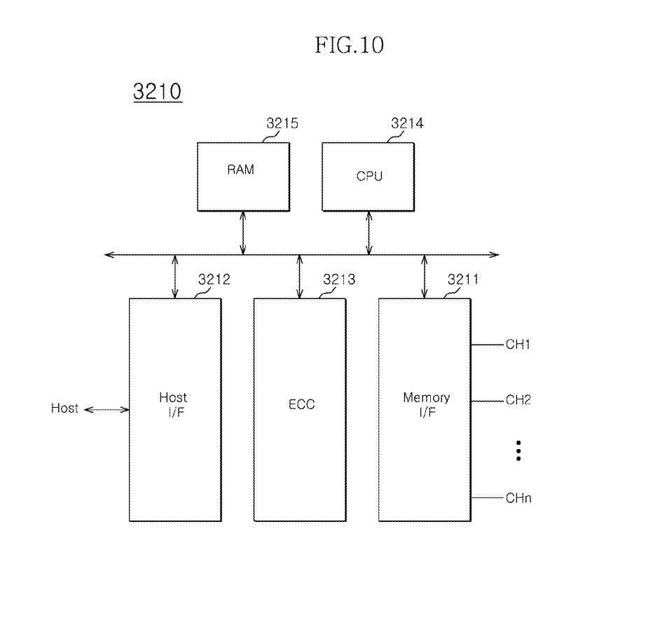

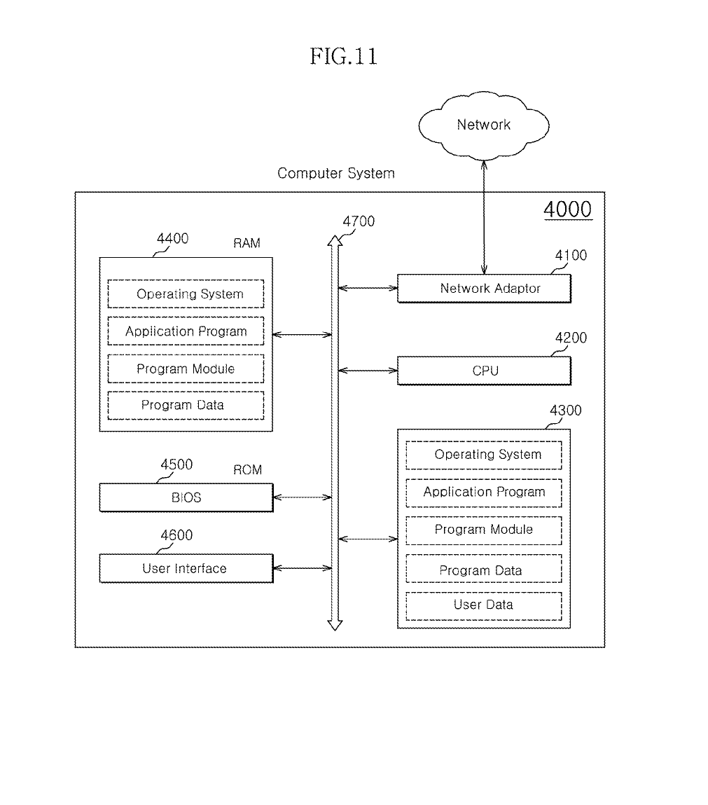

FIG. 10 is a block diagram illustrating the SSD controller illustrated in FIG. 9. Referring to FIG. 10, the SSD controller 3210 may include a memory interface 3211, a host interface 3212, an ECC unit 3213, a CPU 3214, and a RAM 3215.

The memory interface 3211 may be configured to provide a command and an address to the nonvolatile memory devices 3231 to 323n. Furthermore, the memory interface 3211 may be configured to exchange data with the nonvolatile memory devices 3231 to 323n. The memory interface 3211 may scatter data transferred from the buffer memory device 3220 over the respective channels CH1 to CHn, according to the control of the CPU 3214. Furthermore, the memory interface 3211 transfers data read from the nonvolatile memory devices 3231 to 323n to the buffer memory device 3220, according to the control of the CPU 3214.

The host interface 3212 may be configured to provide an interface with the SSD 3200 in response to the protocol of the host 3100. For example, the host interface 3212 may be configured to communicate with the host 3100 through one of PATA (Parallel Advanced Technology Attachment), SATA (Serial Advanced Technology Attachment), SCSI (Small Computer System Interface), SAS (Serial SCSI) protocols. Furthermore, the host interface 3212 may perform a disk emulation function of supporting the host 3100 to recognize the SSD 3200 as a hard disk drive (HDD).

The ECC unit 3213 may be configured to generate parity bits based on the data transmitted to the nonvolatile memory devices 3231 to 323n. The generated parity bits may be stored in spare areas of the nonvolatile memory devices 3231 to 323n. The ECC unit 3213 may be configured to detect an error of data read from the nonvolatile memory devices 3231 to 323n. When the detected error falls within a correction range, the ECC unit 3213 may correct the detected error.

The CPU 3214 may be configured to analyze and process a signal SGL inputted from the host 3100. The CPU 3214 controls overall operations of the SSD controller 3210 in response to a request of the host 3100. The CPU 3214 controls the operations of the buffer memory device 3220 and the nonvolatile memory devices 3231 to 323n according to firmware for driving the SSD 3200. The RAM 3215 is used as a working memory device for driving the firmware.

FIG. 11 is a block diagram illustrating a computer system in which a data storage device having the nonvolatile memory device according to an embodiment is mounted. Referring to FIG. 11, the computer system 4000 may include a network adapter 4100, a CPU 4200, a data storage device 4300, a RAM 4400, a ROM 4500, and a user interface 4600, which are electrically connected to the system bus 4700. Here, the data storage device 4300 may include the data storage device 1200 illustrated in FIG. 6 or the SSD 3200 illustrated in FIG. 9.

The network adapter 4100 may be configured to provide an interface between the computer system 4000 and external networks. The CPU 4200 may be configured to perform overall arithmetic operations for driving an operating system or application programs staying in the RAM 4400.

The data storage device 4300 may be configured to store overall data required by the computer system 4000. For example, the operating system for driving the computer system 4000, application programs, various program modules, program data, and user data may be stored in the data storage device 4300.

The RAM 4400 may be used as a working memory device of the computer system 4000. During booting, the operating system, application programs, various program modules, which are read from the data storage device 4300, and program data required for driving the programs are loaded into the RAM 4400. The ROM 4500 stores a basic input/output system (BIOS) which is enabled before the operating system is driven. Through the user interface 4600, information exchange is performed between the computer system 4000 and a user.

Although not illustrated in the drawing, the computer system 4000 may further include a battery, application chipsets, a camera image processor (CIP) and the like.

While various embodiments have been described above, it will be understood to those skilled in the art that the embodiments described are by way of example only. Accordingly, the nonvolatile memory device described herein should not be limited based on the described embodiments.

What is claimed is:

1. A nonvolatile memory device comprising:
a plurality of memory cells arranged at a region where word lines and bit lines cross each other;
a plurality of data read/write circuits divided into a plurality of groups, and configured to store data in the memory cells or read data stored in the memory cells, according to an operation mode;
a pass/fail check unit configured to determine a pass/fail of an operation for each of the data read/write circuit groups; and
a current sensing check unit configured to selectively perform a fail bit count operation on the data read/write circuit groups, according to a determination result of the pass/fail check unit.

2. The nonvolatile memory device according to claim 1, wherein the current sensing check unit is configured to perform the fail bit count operation on a data read/write circuit group whose operation was determined to be a fail by the pass/fail check unit.

3. The nonvolatile memory device according to claim 2, wherein the current sensing check unit compares a reference voltage to the magnitude of a pass/fail signal provided from the data read/write circuit group whose operation was determined to be a fail, and output information on whether a fail bit number of the data read/write circuit group whose operation was determined to be a fail is greater or less than a threshold value, based on the comparison result.

4. The nonvolatile memory device according to claim 3, wherein the reference voltage is set according to the threshold value.

5. The nonvolatile memory device according to claim 1, wherein the pass/fail check unit comprises a plurality of pass/fail check circuits corresponding to the respective data read/write circuit groups.

6. The nonvolatile memory device according to claim 5, wherein each of the pass/fail check circuits provides a pass or fail result of operation for the corresponding data read/write circuit group to the current sensing check unit.

7. The nonvolatile memory device according to claim 6, wherein the pass/fail check circuit further comprises:
a pass/fail sensing node configured for receiving pass/fail signals outputted from the read/write circuits and to receive a power supply voltage based on a pass/fail check bar signal; and
a NAND gate configured to perform a NAND operation on a state of the pass/fail sensing node and a pass/fail check signal, and output the pass or fail result operation.

8. The nonvolatile memory device according to claim 7, wherein the pass/fail sensing node receives the power supply voltage from a pull-up element.

9. The nonvolatile memory device according to claim 8, wherein the read/write circuits comprise a pull-down element for providing the pass/fail signals.

10. An operating method of a nonvolatile memory device, comprising the steps of:
determining whether an operation of a data read/write circuit group including a plurality of data read/write circuits is passed or failed; and
when the operation of the data read/write circuit group is failed, counting a fail bit number of the data read/write circuit group.

11. The operating method of claim 10, wherein the step of determining whether the operation of the data read/write circuit group is passed or failed is repeated until the step is performed on all data read/write circuit groups.

12. The operating method of claim 10, wherein the step of counting the fail bit number of the data read/write circuit group comprises the steps of:
comparing a reference voltage to a voltage of a pass/fail sensing node of the data read/write circuit group; and
outputting information on whether the fail bit number of the data read/write circuit group is greater or less than a threshold value, according to the comparison result.

13. A data storage device comprising:
a nonvolatile memory device; and
a controller configured to control the nonvolatile memory device,
wherein the nonvolatile memory device comprises:
a plurality of memory cells arranged at a region where word lines and bit lines cross each other;
a plurality of data read/write circuits divided into a plurality of groups, and configured to store data in the memory cells or read data stored in the memory cells, according to an operation mode;
a pass/fail check unit configured to determine a pass/fail of an operation for each of the data read/write circuit groups; and
a current sensing check unit configured to selectively perform a fail bit count operation on the data read/write circuit groups, according to a determination result of the pass/fail check unit.

14. The data storage device according to claim 13, wherein the current sensing check unit is configured to perform the fail bit count operation on a data read/write circuit group whose operation was determined to be a fail by the pass/fail check unit.

15. The data storage device according to claim 14, wherein the current sensing check unit compares a reference voltage to the magnitude of a pass/fail signal provided from the data read/write circuit group whose operation was determined to be a fail, and output information on whether a fail bit number of the data read/write circuit group whose operation was determined to be a fail is greater or less than a threshold value, based on the comparison result.

16. The data storage device according to claim 15, wherein the reference voltage is set according to the threshold value.

17. The data storage device according to claim 13, wherein the pass/fail check unit comprises a plurality of pass/fail check circuits corresponding to the respective data read/write circuit groups.

18. The data storage device according to claim 17, wherein each of the pass/fail check circuits provides a pass or fail result of operation for the corresponding data read/write circuit group to the current sensing check unit.

19. The nonvolatile memory device according to claim 18, wherein the pass/fail check circuit further comprises:
a pass/fail sensing node configured for receiving pass/fail signals outputted from the read/write circuits and to receive a power supply voltage based on a pass/fail check bar signal; and
a NAND gate configured to perform a NAND operation on a state of the pass/fail sensing node and a pass/fail check signal, and output the pass or fail result operation.

20. The nonvolatile memory device according to claim 19, wherein the pass/fail sensing node receives the power supply voltage from a pull-up element.

21. The nonvolatile memory device according to claim 20, wherein the read/write circuits comprise a pull-down element for providing the pass/fail signals.

22. The nonvolatile memory device according to claim 13, wherein the nonvolatile memory device and the controller are configured as a memory card.

23. The nonvolatile memory device according to claim 13, wherein the nonvolatile memory device and the controller are configured as a solid state drive (SSD).
